(19) United States
(12) Patent Application Publication
(10) Pub. No.: US 2010/0300511 A1
(43) Pub. Date: Dec. 2, 2010

(54) Power supply device with built-in radio

(76) Inventor: Ko-Chien Chu, Kweishan Hsiang (TW)

Correspondence Address: PRO-TECHTOR INTERNATIONAL SERVICES, 20775 NORADA CT., SARATOGA, CA, 95070, US

(21) Appl. No.: 12/471,685

(22) Filed: May 26, 2009

(51) Int. Cl. H01L 31/00

(52) U.S. Cl. 136/252

(57) ABSTRACT

A power supply device with a built-in radio includes: a casing having a top side with an opening and a rear side with a large through hole, coupled to a covering plate from above and a rear cover from behind, and connected to two handles; a solar chip set disposed on an outer surface of the covering plate; a photoelectric converter provided beneath the covering plate; a cell fixed inside the casing by a cell pad and a front cover, penetrating the large through hole, and connected to the photoelectric converter and a control circuit board connected to at least a power connector, connector indicator, and connector switch that are provided on a front side of the easing; and a radio circuit board connected to the control circuit board and connected to an operation and display panel, loudspeaker, and antenna that are provided on the front side of the casing.

### BACKGROUND OF THE INVENTION

1. Technical Field

The present invention re hues to power supplies independent of the utility grid, and more particularly, to a solar-powered power supply device with a built-in radio.

2. Description of Related Art

The utility grid, as a power source, is economically benefit yet not environmentally friend for it typically originates from energy resources that are not renewable and sustainable. Hence, solar power is becoming more important as a solution to the energy issue. Existing technology of solar power generation involves using silicon chips as receiving interfaces for turning light energy into electrical energy at a conversion rate of 12% to 17%. Solar power generation not only slows down exploitation of petroleum-based energy resources but also protects environment by reducing carbon emission. Also, solar energy captured in the daytime can be stored up for later use. In recent years, many outdoor lighting devices have been developed under such a principle. However, the solar-powered power supply devices have been proven to be structurally unfit for application other than outdoor lighting, thus being short of industrial applicability. In view of the aforesaid drawback of the prior art, the inventor of the present invention is devoted to research with a view to overcoming the aforesaid drawback of the prior art.

### SUMMARY OF THE INVENTION

It is an objective of the present invention to provide a solar-powered power supply device with a built-in radio, wherein the power supply device converts light energy into electrical energy lo be stored in a cell for later use, and thus the power supply device per se functions as a power supply directly operable or rechargeable by external electronic devices.

Another objective of the present invention is to provide a solar-powered power supply device with a built-in radio whereby users are allowed to enjoy radio broadcasts with renewable energy resources.

To achieve the above and other objectives, the present invention provides a power supply device with a built-in radio. The power supply device comprises a casing having a top side with an opening thereon and a rear side with a large through hole thereon, coupled to a covering plate from above and a rear cover from behind, and flanked by two handles connected thereto; a solar chip set disposed on an outer surface of the covering plate; a photoelectric converter provided inside the casing and beneath the covering plate; a cell fixed in position inside the casing by a cell pad and a front cover thereof, penetrating the large through hole, and connected to the photoelectric converter and a control circuit board; a radio circuit board connected to the control circuit board and connected to an antenna, a loudspeaker, and an operation and display panel fixed in position on a front side of the casing; and at least a power connector, at least a connector switch, and at least a connector indicator fixed in position on the front side of the casing and connected to the control circuit board.

### BRIEF DESCRIPTION OF THE DRAWINGS

The invention as well as a preferred mode of use, further objectives, and advantages thereof will be best understood by reference to the following detailed description of an illustrative embodiment when read in conjunction with the accompanying drawings, wherein:

FIG. 1 is an exploded view of the present invention;

FIG. 2 is a perspective view of the present invention;

FIG. 3 is a front view of the present invention;

FIG. 4 is a rear view of the present invention; and

FIG. 5 is a from view of another embodiment of the present invention.

### DETAILED DESCRIPTION OF THE PREFERRED EMBODIMENTS

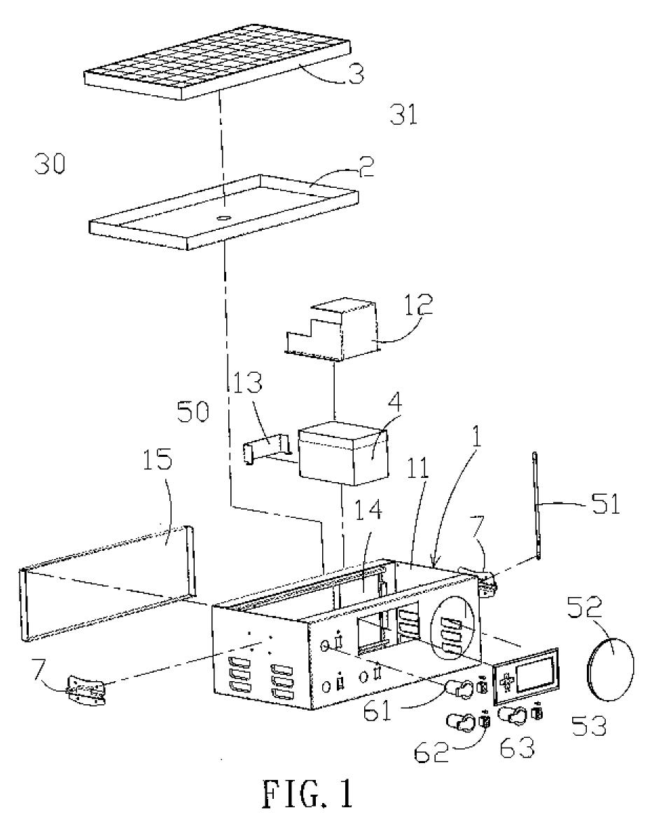

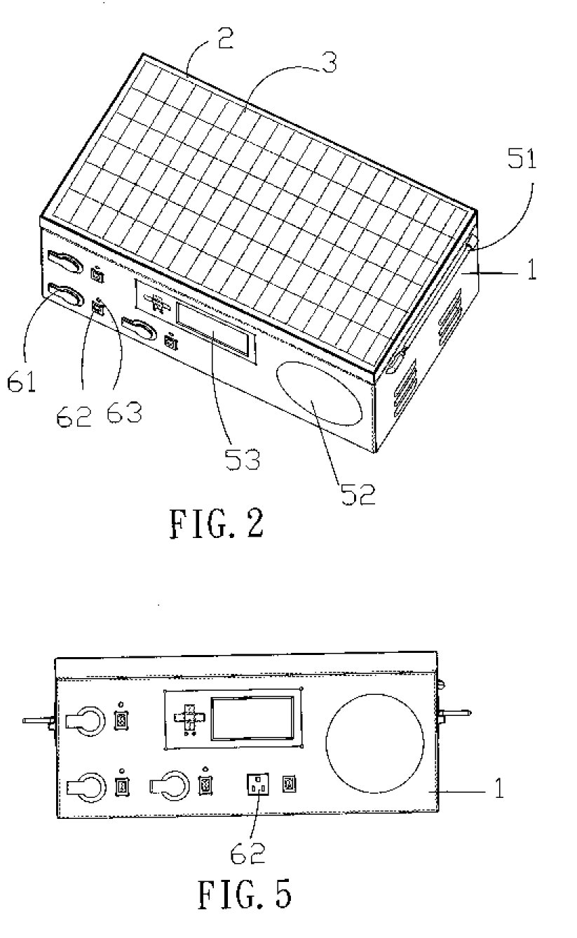

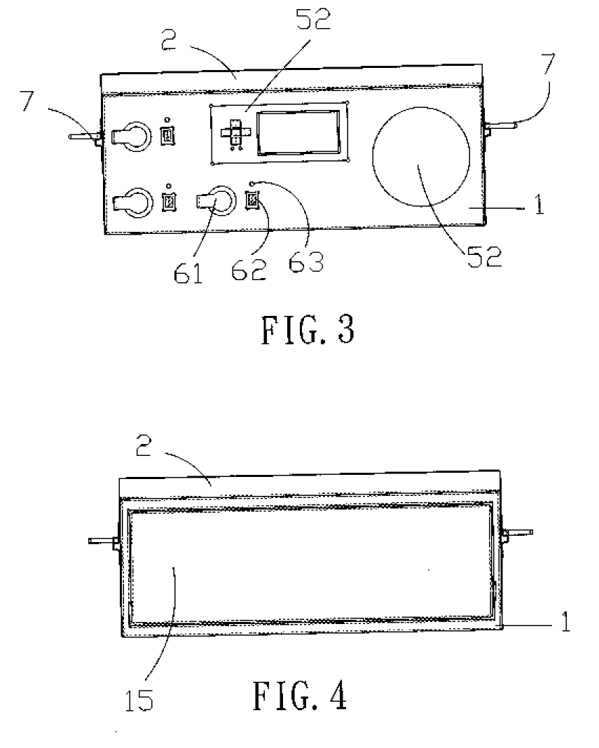

Referring to FIGS. 1 through 5, a power supply device with a built-in radio of the present invention comprises a casing 1, a solar chip set 3, a photoelectric converter, a cell 4, a radio circuit board, and at least a power connector. The casing 1 has a top side with an opening 11 thereon and is coupled to a covering plate 2 from above. The solar chip set 3 is disposed on an outer surface of the covering plate 2. The photoelectric converter 31 is provided inside the casing 1 and beneath the covering plate 2. The cell 4 is fixed in position inside the casing by a cell pad 12 and a front cover 13 thereof, penetrates the large through hole, and is connected to the photoelectric converter 31 and a control circuit board 30. The casing 1 has a rear side with a large through hole 14 thereon, and the large through hole 14 can be penetrated by the cell 4 lo facilitate changing of the cell. The casing 1 is coupled to a rear cover 15 from behind. The cell 4 is connected to a photoelectric converter 31 and a control circuit board 30. The control circuit board 30 is connected to a radio circuit board 50. The radio circuit board is connected to an antenna 51, a loudspeaker 52, and an operation and display panel 53 fixed in position on a front side of the casing 1. The control circuit board is connected to at least a power connector 61 (three in the drawing), at least a connector switch 62, and at least a connector indicator 63 fixed in position on the front cover of the casing 1. The casing 1 is flanked by two handles 7 connected thereto. The power connector 61 is a power socket 64 (shown in FIG. 5), a lighter socket (shown in FIG. 1 through FIG. 4), a USB socket, or a combination thereof. Optionally, a lighter plug can be connected to connectors of whatever types so as to form a plug.

In conclusion, the disclosed power supply device integrated with the built-in radio provides functions of power supplying and radio broadcasting in one structure. It is configured for direct use and also serves for power level monitoring. Besides, while being equipped with various power connectors, the power supply device is capable of supplying power to various external electronic products. Hence, the power supply device with the built-in radio of the present invention has high industrial applicability and novelty over the prior art.

The foregoing preferred embodiment is only illustrative of the features and functions of the present invention but are not intended to restrict the scope of the present invention. It is apparent to those skilled in the art that all equivalent modifications and variations made in the foregoing preferred embodiment according to the spirit and principle in the disclosure of the present invention should fall within the scope of the appended claims.

What is claimed is:

1. A power supply device with a built-in radio, the power supply device comprising:
a casing, having a top side formed with an opening and a rear side formed with a large through hole while being coupled to a covering plate from above and a rear cover from behind;
a solar chip, set disposed on an outer surface of the covering plate;
a photoelectric converter, provided inside the casing and beneath the covering plate;
a cell, fixed in position inside the casing, penetrating the large through hole, and connected to the photoelectric converter and a control circuit board;
a radio circuit board, connected to the control circuit board and connected to an antenna, a loudspeaker, and an operation and display panel that are fixed in position on a front side of the casing; and
at least a power connector fixed in position on the front side of the casing and connected to the control circuit board.

2. The device of claim 1, wherein the control circuit board is connected to at least a connector indicator and at least a connector switch that are fixed in position on the front side of the easing.

3. The device of claim 1, wherein the cell is fixed in position inside the casing by a cell pad and a front cover of the cell pad.

4. The device of claim 1, wherein the power connector is one selected from the group consisting of a power socket a lighter socket, a USB socket, and a combination thereof.

5. The device of claim 1, wherein the casing is flanked by two handles connected thereto.
